(19) United States
(12) Patent Application Publication
(10) Pub. No.: US 2014/0340959 A1
(43) Pub. Date: Nov. 20, 2014

(54) NONVOLATILE MEMORY DEVICE AND DATA PROCESSING METHOD THEREOF

(71) Applicant: Artur Antonyan, Suwon-si (KR)

(72) Inventor: Artur Antonyan, Suwon-si (KR)

(21) Appl. No.: 14/149,248

(22) Filed: Jan. 7, 2014

(30) Foreign Application Priority Data
May 16, 2013 (KR) 10-2013-0055846

(51) Int. Cl. G11C 11/16

(52) U.S. Cl. CPC G11C 11/1673; G11C 11/1675
USPC 365/158; 365/189.011; 365/194; 365/189.07

(57) ABSTRACT

A nonvolatile memory device is provided comprising a memory cell array including first and second memory cells. Data is stored at the first memory cell. The device further comprises an access control circuit configured to read the data stored at the first memory cell and to subsequently perform a data processing operation on the second memory cell contemporaneously with a reprogramming operation performed on the first memory cell. The reprogramming operation on the first memory cell is selectively performed based on a determination whether a state of the first memory cell is changed while the data stored at the first memory cell is read.

### CROSS-REFERENCE TO RELATED APPLICATIONS

This U.S. non-provisional application claims priority under 35 U.S.C. §119 to Korean Patent Application No. 10-2013-0055846, filed on May 16, 2013 in the Korean Intellectual Property Office, the contents of which is incorporated herein by reference in its entirety.

### BACKGROUND

1. Field

The inventive concepts described herein relate to a nonvolatile memory device, and more particularly, to a resistive random access memory device and a data processing method thereof.

2. Background

A magnetic random access memory (MRAM) may be a device that stores data using a resistance variation in a magnetic tunneling junction (MTJ) element of a memory cell. A resistance value of the MTJ element may vary according to a magnetization direction of a free layer. For example, when a magnetization direction of the free layer is parallel with that of a fixed layer, the MTJ element may have a relatively small resistance value. When a magnetization direction of the free layer is not parallel with that of the fixed layer, the MTJ element may have a relatively large resistance value. A relatively small resistance value of the MTJ element may correspond to a data value ‘0’ and a relatively large resistance value may correspond to a data value ‘1’.

The MRAM may write data using a data writing method in which data is written at the MTJ element using a digit line. Here, a current may be applied to a digit line spaced apart from the MTJ element to generate a magnetic field, and a magnetization direction of the free layer may be changed by the magnetic field. A read current may be applied between both ends of the MTJ element. In the MRAM, a read current path may be different from a write current path. However, in a spin transfer torque magnetic random access memory (STT-MRAM) not employing a digit line, a read current path may be equal to a write current path. For this reason, precise control is required with respect to both read and write currents.

### SUMMARY

An object of the inventive concept is directed to provide a nonvolatile memory device capable of performing a reprogramming operation on a memory cell the state of which is varied at a read operation, without additional waste of time.

One aspect of the inventive concept is directed to a nonvolatile memory device comprising a memory cell array including first and second memory cells. Data is stored at the first memory cell. The device further comprises an access control circuit configured to read the data stored at the first memory cell and to subsequently perform a data processing operation on the second memory cell contemporaneously with a reprogramming operation performed on the first memory cell. The reprogramming operation on the first memory cell is selectively performed based on a determination whether a state of the first memory cell is changed while the data stored at the first memory cell is read.

In some embodiments, the first and second memory cells share a common line, and the access control circuit generates a base voltage that is output to the common line during the reprogramming operation performed on the first memory cell. The base voltage is higher than a ground voltage and lower than a power supply voltage.

In some embodiments, the common line includes a source line shared by the first and second memory cells.

In some embodiments, the common line includes a bit line shared by the first and second memory cells.

In some embodiments, the memory cell array includes one or more spin transfer torque magnetic random access memory (STT-MRAM) cells.

In some embodiments, the access control circuit comprises: a sensing current source configured to provide the first memory cell with a sensing current variable between a first level and a second level, and the access control circuit reads data stored at the first memory cell in response to whether a state of the first memory cell is changed while the sensing current is provided.

In some embodiments, the reprogramming operation of the first memory cell is selectively performed in response to whether a state of the first memory cell is changed while the sensing current is provided.

In some embodiments, the first level is higher than a low switching current level and lower than a high switching current level, and the low switching current level is a current level by which a state of the first memory cell is switched from a low resistance state to a high resistance state and the high switching current level is a current by which a state of the first memory cell is switched from the high resistance state from the low resistance state.

In some embodiments, the second level is higher than the high switching current level, and in response to a state of the first memory cell being changed while the sensing current is provided, data stored at the first memory cell is determined as data corresponding to a high resistance state.

In some embodiments, the second level is lower than the low switching current level, and wherein in response to a state of the first memory cell being changed while the sensing current is provided, data stored at the first memory cell is determined as data corresponding to a low resistance state.

In some embodiments, the access control circuit further comprises: a sensing current source providing a sensing voltage output from the first memory cell in response to the sensing current; a delay circuit configured to delay the sensing voltage to output the delayed sensing voltage to a delay node; and a sense amplifier configured to provide an output voltage in response to a difference between the sensing voltage and the delayed sensing voltage, and whether a state of the first memory cell is changed while the sensing current is provided is determined based on the output voltage.

In some embodiments, the delay circuit comprises an element including a resistor and a capacitor.

Another aspect of the inventive concept is directed to a data processing method of a nonvolatile memory device, comprising: determining whether a state of a first memory cell is changed while data stored at the first memory cell is read; reprogramming the first memory cell when a state of the first memory cell is changed; and performing a data processing operation on the second memory cell during a reprogramming operation performed on the first memory cell.

In some embodiments, determining whether a state of the first memory cell is changed while data stored at the first memory cell is read comprises: providing the first memory cell with a sensing current variable from a first level to a second level; determining whether the state of the first memory cell is changed during an application of the sensing current; and processing the data stored at the first memory cell in response to the determination whether a state of the first memory cell is changed.

In some embodiments, performing a data processing operation on the second memory cell during reprogramming of the first memory cell comprises: determining whether a common line shared by the first and second memory cells exists; and in response to a determination that the common line exists, providing the common line with a base voltage higher than a ground voltage and lower than a power supply voltage.

Another aspect of the inventive concept is directed to a nonvolatile memory device comprising a plurality of memory cells. The memory cells comprises a first memory cell and a second memory cell, the first memory cell storing data. The device further comprises an access control circuit that reads the data stored at the first memory cell and determines whether a state of the first memory cell is changed while the data stored at the first memory cell is read, and that performs a data processing operation on the second memory cell during a reprogramming operation performed on the first memory cell.

In some embodiments, the nonvolatile memory device further comprises a common line, wherein the common line comprises at least one of a bit line and a source line shared by the first and second memory cells.

In some embodiments, at least one of the first memory cell and the second memory cell includes one or more spin transfer torque magnetic random access memory (STT-MRAM) cells.

In some embodiments, the data processing operation performed on the second memory cell includes at least one of a read operation and a write operation.

In some embodiments, the access control unit provides the first memory cell with a sensing current variable from a first level to a second level, determines whether the state of the first memory cell is changed during an application of the sensing current, and processes the data stored at the first memory cell in response to the determination made by the access control unit whether the state of the first memory cell is changed.

### BRIEF DESCRIPTION OF THE FIGURES

The above and other objects and features will become apparent from the following description with reference to the following figures, wherein like reference numerals refer to like parts throughout the various figures unless otherwise specified, and wherein

FIG. 1 is a block diagram schematically illustrating a nonvolatile memory device according to an embodiment of the inventive concept;

FIG. 2 is a diagram schematically illustrating a memory cell of a cell array of FIG. 1 according to an embodiment of the inventive concept;

FIGS. 3 and 4 are diagrams illustrating magnetization directions of a variable resistance element according to data stored at a memory cell of FIG. 2;

FIG. 5 is a diagram describing a write operation on a memory cell of FIG. 2;

FIG. 6 is a graph illustrating the relationship between a current flowing to a variable resistance element and a resistance value of the variable resistance element, according to an embodiment of the inventive concept;

FIG. 7 is a flow chart of a read method of a nonvolatile memory device, according to an embodiment of the inventive concept;

FIG. 8 is a timing diagram schematically illustrating a read method of a nonvolatile memory device of FIG. 7;

FIG. 9 is a circuit diagram of a detector coupled to a memory cell, in accordance with an embodiment;

FIG. 10 is a graph schematically illustrating a relationship between a sensing current and a resistance value of a memory cell;

FIG. 11 are diagrams describing an output voltage when a memory cell is at a low resistance state before a read operation;

FIG. 12 are diagrams describing an output voltage when a memory cell is at a high resistance state before a read operation;

FIG. 13 is a flow diagram of an embodiment on operations of reading data stored at a first memory cell and determining whether a state of the first memory cell is changed, in a read method of a nonvolatile memory device of FIG. 7;

FIG. 14 is a diagram of a first memory cell and memory cells adjacent to the first memory cell;

FIG. 15 is a diagram describing a data processing operation in the event that a first memory cell and a second memory cell share a same source line;

FIG. 16 is a diagram for describing a data processing operation in the event that a first memory cell and a second memory cell share the same bit line;

FIG. 17 is a flow diagram describing an operation that includes performing a data processing operation on a second memory cell during execution of a reprogramming operation on a first memory cell, in accordance with an embodiment;

FIG. 18 is a block diagram schematically illustrating a portable electronic system including a phase change memory device constructed and arranged as a nonvolatile memory device according to an embodiment of the inventive concept;

FIG. 19 is a block diagram schematically illustrating a memory card including a nonvolatile memory device according to an embodiment of the inventive concept; and

FIG. 20 is a diagram schematically illustrating various systems to which a memory card in FIG. 19 can be applied.

### DETAILED DESCRIPTION

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

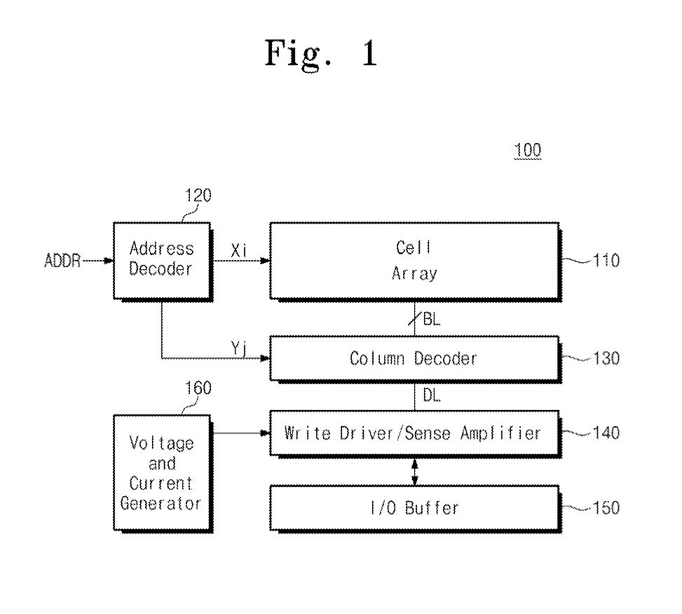

FIG. 1 is a block diagram schematically illustrating a nonvolatile memory device 100 according to an embodiment of the inventive concept. The nonvolatile memory device 100 may include a cell array 110, an address decoder 120, a column decoder 130, a write driver and sense amplifier block 140, an input/output (I/O) buffer 150, and a voltage and current generator 160. Components 120 to 160 may constitute an access control circuit that controls the cell array 110.

If a state of a first memory cell is changed during a read operation of the first memory cell, then the nonvolatile memory device 100 may reprogram the first memory cell to have a predetermined state before the read operation is performed. The nonvolatile memory device 100 may perform a read or write operation on a second memory cell while the first memory cell is reprogrammed.

That is, the nonvolatile memory device 100 may simultaneously perform a reprogramming operation and a data processing operation with respect to a plurality of memory cells having different addresses. The nonvolatile memory device 100 may perform a data processing operation in fast operating speed and with high reliability.

The cell array 110 may include a plurality of nonvolatile memory cells. For example, the cell array 110 may be formed of memory cells such as resistive memory cells, e.g., PRAM (Phase Change Random Access Memory) or RRAM (Resistance Random Access Memory) cells, NFGM (Nano Floating Gate Memory) cells, PoRAM (Polymer Random Access Memory) cells, MRAM (Magnetic Random Access Memory) cells, or FRAM (Ferroelectric Random Access Memory) cells, of a combination thereof.

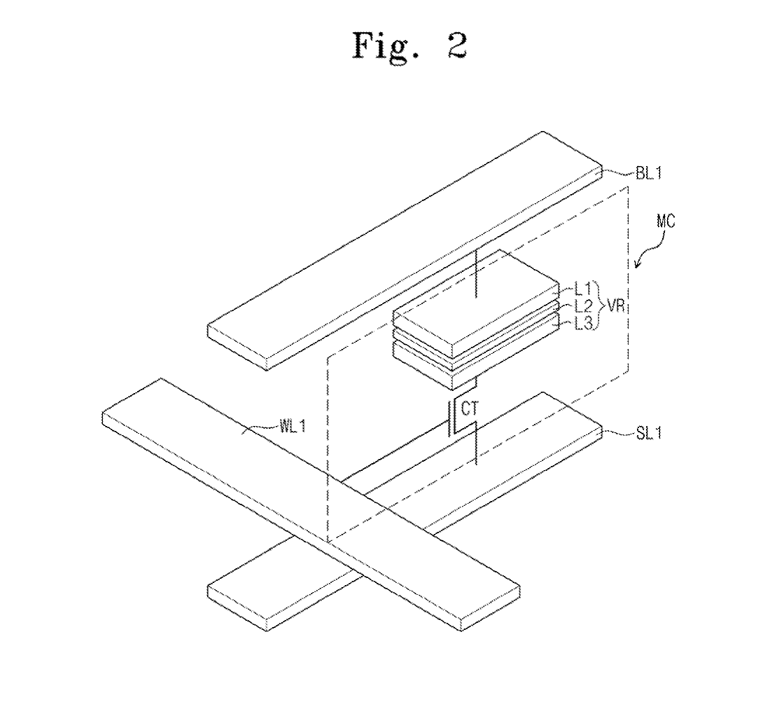

In example embodiments, the cell array 110 may be formed of STT-MRAM (Spin Transfer Torque Magneto Resistive Random Access Memory) cells. The STT-MRAM cells will be more fully described with reference to FIGS. 2 to 5.

The memory cells in the cell array 110 may be selected by a row address Xi and a column address Yj, where i and j are integers greater than 0. At least one word line may be selected by the row address Xi, and at least one bit line may be selected by the column address Yj.

The address decoder 120 may decode an input address ADDR into the row address Xi and the column address Yj. The address decoder 120 may select one of the word lines according to the row address Xi. Also, the address decoder 120 may output the column address Yj to the column decoder 130. The column decoder 130 may select a data line DL with a selected bit line BL in response to the column address Yj.

The write driver and sense amplifier block 140 may receive data from the input/output buffer 150 at a program operation. The write driver and sense amplifier block 140 may receive a write current for writing input data at a selected memory cell from the voltage and current generator 160.

The write driver and sense amplifier block 140 may sense data written at the selected memory cell. The write driver and sense amplifier block 140 may amplify the sensed data to convert it into a binary logic value. The write driver and sense amplifier block 140 may transfer the converted data to the input/output buffer 150.

The write driver and sense amplifier block 140 may provide a read current to the data line DL to read data of the selected memory cell. The write driver and sense amplifier block 140 may compare a voltage of the data line DL measured using the read current with a reference voltage. The write driver and sense amplifier block 140 may determine a data value, e.g., a logical 0 or a logical 1, written at a memory cell according to the comparison result. The write driver and sense amplifier block 140 may be supplied with a read current supplied to the data line DL from the voltage and current generator 160.

The input/output buffer 150 may temporarily store input data, for outputting the input data to the write driver and sense amplifier block 140. Also, the input/output buffer 150 may temporarily store output data provided from the write driver and sense amplifier block 140, for outputting it to an external device.

The voltage and current generator 160 may generate an operating voltage and an operating voltage for an operation of the nonvolatile memory device 100. The operating voltage may include voltages to be provided to bit lines BL and word lines connected to the cell array 110. The operating current may include read and write currents for performing a data processing operation on memory cells.

To determine whether to perform a reprogramming step based on data read from a memory cell of the cell array 110, the voltage and current generator 160 may provide a sensing current which is varied from a minimum current to a maximum current. The sensing current and a data processing operation using the sensing current is more fully described herein with reference to FIGS. 9 to 13.

The voltage and current generator 160 may generate a base voltage to perform data processing operations on a plurality of memory cells having different addresses at the same time. The base voltage may be provided to a common line, for example, a bit line or a source line, which is shared by a plurality of memory cells where data processing operations are simultaneously performed. The base voltage and a data processing operation using the base voltage is more fully described herein with reference to FIGS. 14 to 16.

Since the nonvolatile memory device 100 simultaneously performs a reprogramming operation and a data processing operation with respect to a plurality of memory cells having different addresses, it may perform a data processing operation at a fast operating speed and with high reliability.

FIGS. 2 to 6 are diagrams for describing a physical characteristic of a memory cell included in a nonvolatile memory device 100.

FIG. 2 is a diagram schematically illustrating a memory cell of a cell array of FIG. 1 according to an embodiment of the inventive concept. In FIG. 2, a memory cell may be an STT-MRAM cell.

The memory cell may include a variable resistance element VR and a cell transistor CT. A gate of the cell transistor CT may be connected with a word line (e.g., WL1). One electrode of the cell transistor CT may be connected with a bit line (e.g., BL1) via the variable resistance element VR. The other electrode may be connected with a source line (e.g., SL1).

The variable resistance element VR may include a free layer L1, a fixed layer L3, and a tunnel layer L2 interposed between the free layer L1 and the fixed layer L3. A magnetization direction of the fixed layer L3 may be fixed. A magnetization direction of the free layer L1 may be parallel with or anti-parallel with a magnetization direction of the fixed layer L3 according to a condition. The variable resistance element VR may further include an anti-ferromagnetic layer (not shown) to fix a magnetization direction of the fixed layer L3.

At a read operation, a high-level voltage may be applied to the word line WL1. At this time, the cell transistor CT may be turned on. Also, a read current may be provided in a direction from the bit line BL1 to the source line SL1 to measure a resistance value of the variable resistance element VR. Data stored at the variable resistance element VR may be determined according to the measured resistance value.

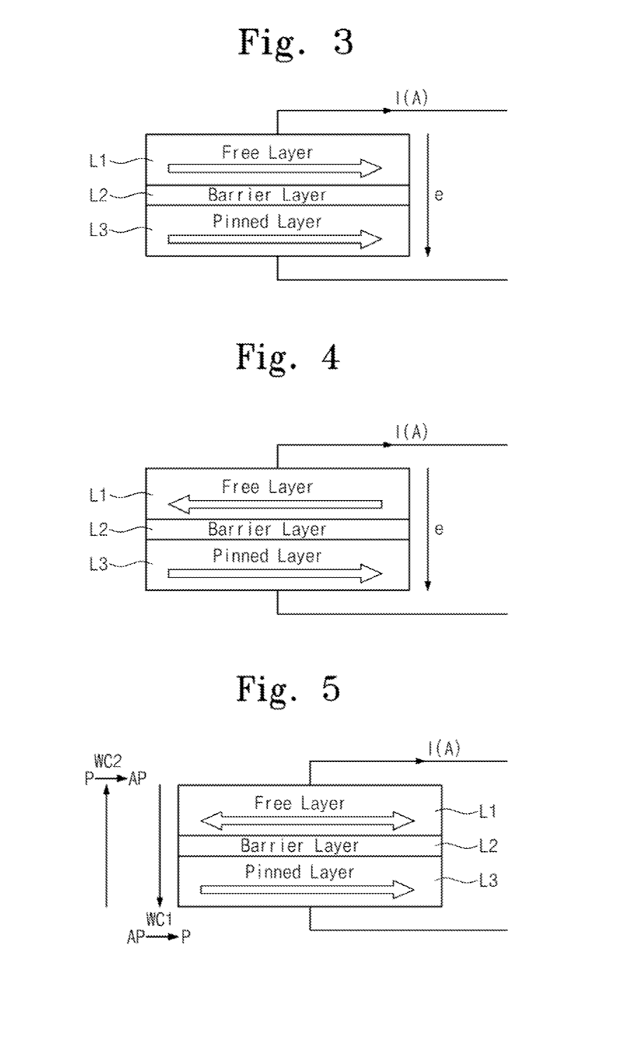

At a write operation, a high-level voltage may be applied to the word line WL1. The cell transistor CT may be activated, or in an on state. Also, a write current may be provided between the bit line BL1 and the source line SL1 to change a resistance value of the variable resistance element VR. The read and write operations are more fully described herein with reference to FIGS. 3 to 5.

FIGS. 3 and 4 are diagrams illustrating magnetization directions of a variable resistance element VR according to data stored at a memory cell of FIG. 2.

A resistance value of a variable resistance element VR may vary according to a magnetization direction of a free layer L1. If a read current I is provided to the variable resistance element VR, a data voltage may be output that corresponds to a resistance value of the variable resistance element VR. Since a read current level is significantly lower than a write current level, in general, a magnetization direction of the free layer L1 may not vary.

Referring to FIG. 3, a magnetization direction of the free layer L1 may be parallel with a magnetization direction of a fixed or pinned layer L3. Thus, the variable resistance element VR may have a small resistance value. In this case, data ‘0’ may be read out from a memory cell, for example, memory cell MC shown in FIG. 2.

Referring to FIG. 4, a magnetization direction of the free layer L1 may be anti-parallel with, or opposite, a magnetization direction of the fixed layer L3. Thus, the variable resistance element VR may have a large resistance value. In this case, data ‘1’ may be read out from the memory cell MC.

In FIGS. 3 and 4, there is illustrated an example in which the free layer L1 and the fixed layer L3 of the variable resistance element VR are formed of horizontal magnetic elements. However, the inventive concept is not limited thereto. For example, the free layer L1 and the fixed layer L3 of the variable resistance element VR can be formed of vertical magnetic elements.

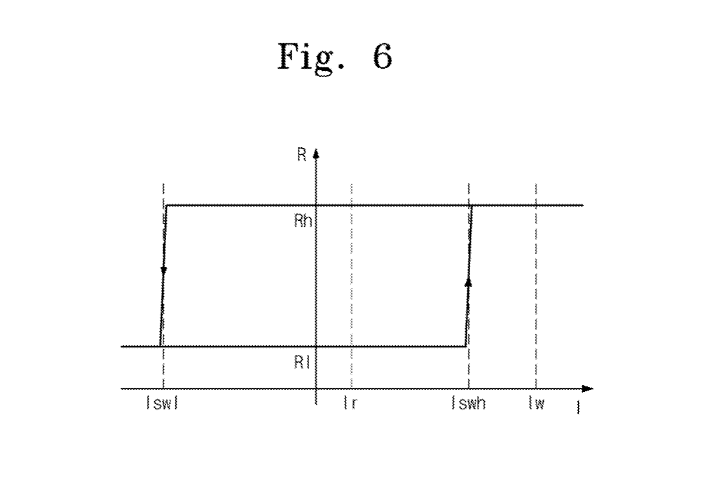

FIG. 5 is a diagram describing a write operation on a memory cell MC of FIG. 2.

Referring to FIG. 5, a magnetization direction of a free layer L1 may be decided according to a direction of a write current WC1/WC2 flowing through a variable resistance element VR. For example, if a first write current WC1 is provided, free electrons having the same spin direction as a fixed layer L3 may apply torque to the free layer L1. The free layer L1 may be magnetized in a manner such that the free layer L1 is parallel with the fixed layer L3.

If a second write current WC2 is provided, free electrons having a spin direction opposite to that of the fixed layer L3 may apply torque to the free layer L1. At this time, the free layer L1 may be magnetized to be anti-parallel with the fixed layer L3. That is, a magnetization direction of the free layer L1 in the variable resistance element VR may be changed by a spin transfer torque.

FIG. 6 is a graph illustrating the relationship between a current flowing to a variable resistance element VR and a resistance value of the variable resistance element, according to an embodiment of the inventive concept.

In FIG. 6, a horizontal axis may indicate a current flowing to a variable resistance element VR, and a vertical axis may indicate a resistance value.

As described with reference to FIGS. 3 and 5, the variable resistance element VR may have two resistance states according to a magnetization direction of a free layer L1 (refer to FIG. 3). For example, the variable resistance element VR may have a low resistance state and a high resistance state.

The variable resistance element VR may exist at a low resistance state when a magnetization direction of the free layer L1 is parallel with a magnetization direction of a fixed layer L3 (refer to FIG. 3). At the low resistance state, the variable resistance element VR may have a first resistance value Rl. The variable resistance element VR may exist at a high resistance state when a magnetization direction of the free layer L1 is anti-parallel with a magnetization direction of the fixed layer L3. At the high resistance state, the variable resistance element VR may have a second resistance value Rh.

As described with reference to FIG. 5, if a sufficient level of current is applied to the variable resistance element VR having a low resistance state, a state of the variable resistance element VR may transition to a high resistance state. If a sufficient level of current is applied to the variable resistance element VR having a high resistance state, a state of the variable resistance element VR may transition to a low resistance state.

In this specification, a minimum current capable of changing the first resistance value Rl of the variable resistance element VR to the second resistance value Rh may be referred to as a high switching current Iswh. A minimum current capable of changing the second resistance value Rh of the variable resistance element VR to the first resistance value Rl may be referred to as a low switching current Iswl. A direction of the high switching current Iswh may be opposite that of the low switching current Iswl.

A level of a write current Iw for changing a resistance state of the variable resistance element VR from a low state to a high state must be higher than that of the high switching current Iswh. Also, a level of a read current Ir may be located between the low switching current Iswl and the high switching current Iswh to prevent a state of the variable resistance element VR from being switched. The read current Ir may be a current for reading a resistance state of the variable resistance element VR.

However, a level of the switching current of the variable resistance element VR may vary according to a time and a circumstance. As a level of the switching current of the variable resistance element VR varies, a state of the variable resistance element VR may vary by the read current Ir at a read operation.

A nonvolatile memory device 100 of FIG. 1 may compensate for a variation in a state of the variable resistance element VR. When a state of a first memory cell varies during a read operation on the first memory cell, the nonvolatile memory device 100 may reprogram the first memory cell to have a state prior to the read operation being formed.

The nonvolatile memory device 100 may perform a read or write operation on a second memory cell while the first memory cell is reprogrammed. That is, since the nonvolatile memory device 100 simultaneously performs a reprogramming operation and a data processing operation with respect to a plurality of memory cells having different addresses, it may perform a data processing operation at a fast operating speed and with high reliability.

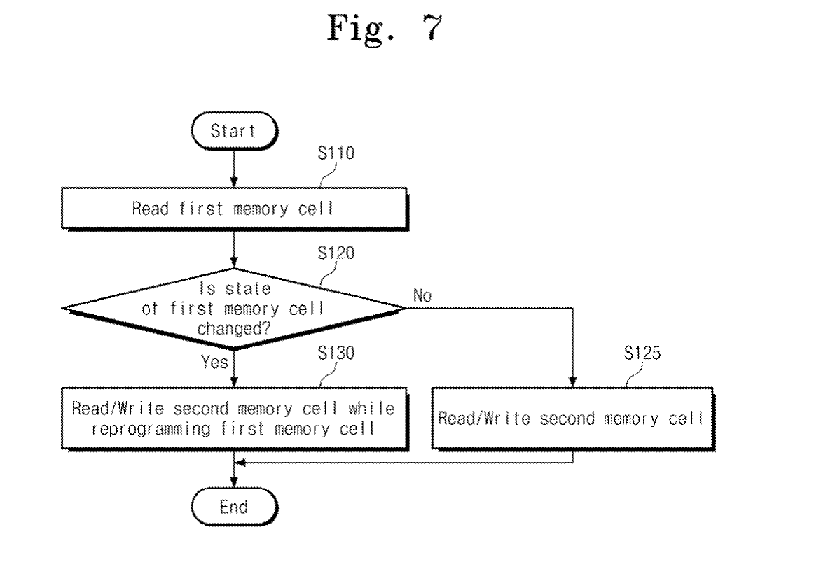

FIG. 7 is a flow chart of a read method of a nonvolatile memory device, according to an embodiment of the inventive concept.

In operation S110, a first memory cell may be read. In particular, data stored at the selected first memory cell may be read out. The data stored at the selected first memory cell may be read out using a read current.

In the operation shown at decision diamond S120, a determination is made whether a state of the first memory cell is changed during the read operation. Whether a state of the first memory cell is changed may be determined using a delay and a sense amplifier. This is more fully described with reference to FIGS. 9 to 12.

If a state of the first memory cell is determined not to be changed during the read operation, the method proceeds to operation S125, wherein a data processing operation may be performed on a second memory cell selected following the first memory cell. The data processing operation on the second memory cell may include a read operation or a write operation.

If a state of the first memory cell is determined to be changed during the read operation, the method proceeds to operation S130, where a reprogramming operation on the first memory cell may be performed. The reprogramming operation may be an operation of programming a state of the first memory cell to have a state before the read operation. A data processing operation on a second memory cell selected following the first memory cell may be performed while the reprogramming operation on the first memory cell may be performed.

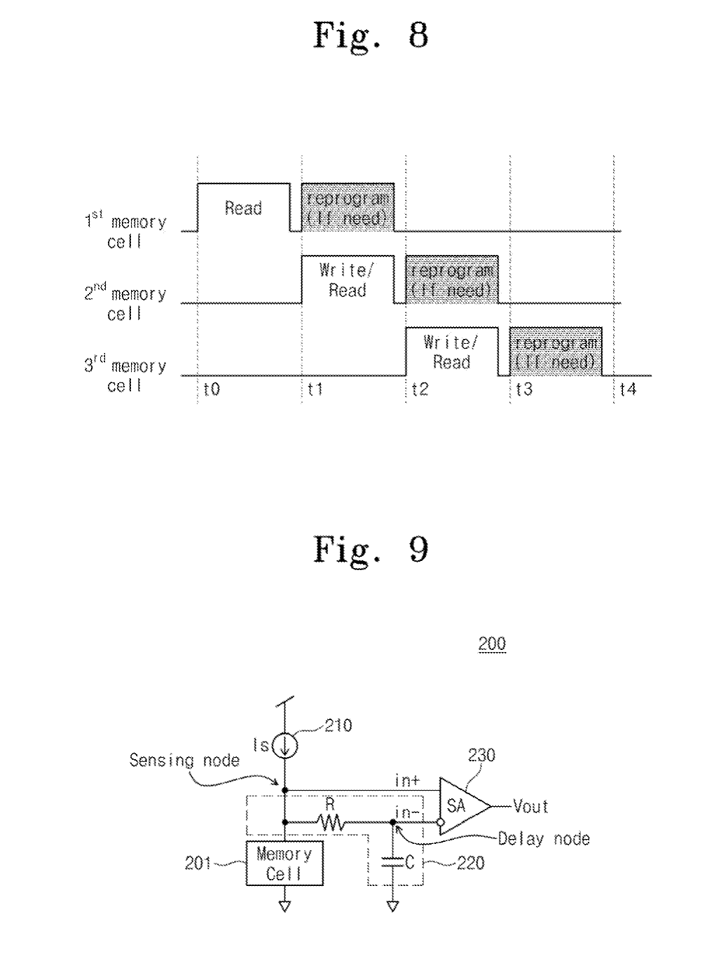

FIG. 8 is a timing diagram of a read method of a nonvolatile memory device of FIG. 7. In FIG. 8, a first memory cell may be a cell selected for data processing. A second memory cell may be a cell selected following the first memory cell. A third memory cell may be a cell selected following the second memory cell.

Referring to FIG. 8, a read operation on the first memory cell may be performed between t0 and t1. A read or write operation on the second memory cell may be performed between times t0 and t1. If a state of the first memory cell is changed between times t0 and t1, a reprogramming operation on the first memory cell may be performed between times t1 and t2.

A read or write operation on the third memory cell may be performed between times t2 and t3. In a case where a read operation on the second memory cell is performed between times t1 and t2, whether a state of the second memory cell is changed between times t1 and t2 may be determined. If a state of the second memory cell is determined to be changed, a reprogramming operation on the second memory cell may be performed between times t2 and t3.

With regard to a read method of the nonvolatile memory device described with reference to FIGS. 7 and 8, a read or write operation on the second memory cell may be executed while a reprogramming operation on the first memory cell is performed. That is, the nonvolatile memory device 100 may simultaneously perform a reprogramming operation and a data processing operation with respect to a plurality of memory cells having different addresses. Thus, the nonvolatile memory device 100 may perform a data processing operation at a fast operating speed and with high reliability.

FIGS. 9 to 13 are diagrams that describe an embodiment on one or more operations, for example, operations S110 and S120 of FIG. 8, the operations related to reading data stored at a first memory cell and determining whether a state of the first memory cell is changed. The operations can relate to a read method of a nonvolatile memory device of FIG. 7.

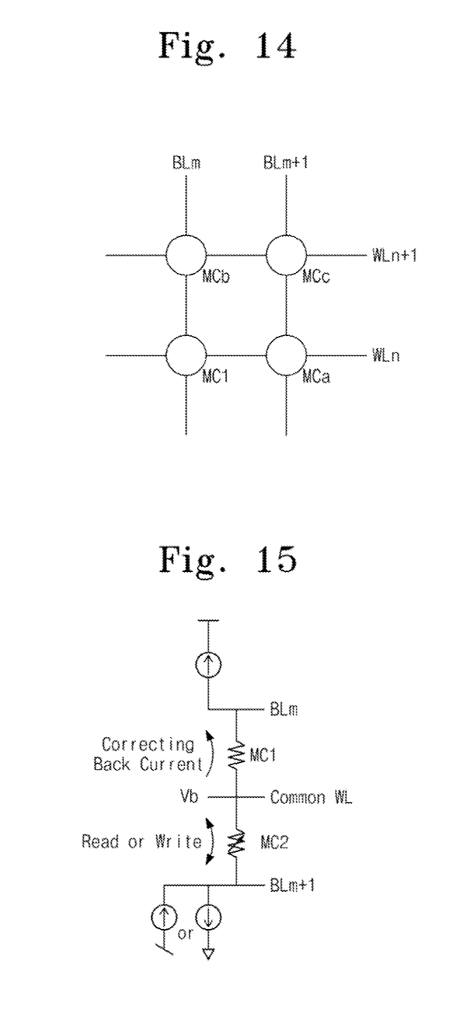

As will be described with reference to FIGS. 9 and 13, a read operation and a state variation determining operation may be simultaneously performed using a variable current source. With the read operation and the state variation determining operation described with reference to FIGS. 9 and 13, a read operation may not need a reference cell. A variation in a physical characteristic of a memory cell is not required.

FIG. 9 is a circuit diagram of a detector 200 coupled to a memory cell 201, in accordance with an embodiment. Referring to FIG. 9, a detector 200 may include a sensing current source 210, a delay circuit 220, and a sense amplifier 230. The detector 200 may read data stored at the memory cell 201 while determining whether a state of the memory cell 201 is changed.

The sensing current source 210 may provide a sensing current Is to the memory cell 201. A level of the sensing current Is may be variable, and may range between a minimum current Imin and a maximum current Imax.

The minimum current Imin may refer to a current at which a state of a memory cell is not changed. A level of the minimum current Imin may be lower than that of a switching current of the memory cell. The maximum current Imax may refer to a current at which a high resistance state of the memory cell is switched into a low resistance state. A level of the maximum current Imax may be higher than that of the switching current of the memory cell.

A resistance value of the memory cell 201 may be changed according to a level of the sensing current Is provided to the memory cell 201. The detector 200 may detect whether a state of the memory cell 201 is changed, over varying a level of the sensing current Is. The detector 200 may read data stored at the memory cell 201 based on the detection result. Also, the detector 200 may request a reprogramming operation on the memory cell 201 based on the detection result. A relationship between the sensing current Is and a resistance value of the memory cell 201 is more fully described with reference to FIG. 10.

FIG. 10 is a graph schematically illustrating a relationship between a sensing current Is and a resistance value of a memory cell. Referring to FIG. 10, as a level of a sensing current Is increases from a minimum current Imin to a maximum current Imax, a resistance value of a memory cell, for example, memory cell 201 of FIG. 9, may gradually decrease.

It is assumed that a memory cell has a high resistance state before applying of the sensing current Is. In this case, a state of the memory cell may be changed from a high resistance state to a low resistance state according to a variation in a level of the sensing current Is.

It is assumed that a memory cell has a low resistance state before applying of the sensing current Is. In this case, the low resistance state of the memory cell may be maintained regardless of a variation in a level of the sensing current Is.

When variation in a level of the sensing current Is is determined, the detector 200 of FIG. 9 may detect whether a state of a memory cell is changed. The detector 200 may read data stored at the memory cell based on the detection result. In the event that a state of the memory cell is changed during a variation in a level of the sensing current Is, data stored at the memory cell may include data corresponding to the high resistance state. If a state of the memory cell is not changed during a variation in a level of the sensing current Is, data stored at the memory cell may include data corresponding to the high resistance state.

Returning to FIG. 9, the detector 200 may include a delay circuit 220 and a sense amplifier 230 that can detect whether a state of a memory cell 201 is changed.

The delay circuit 220 may be connected with a sensing node. The sensing node may be a node which outputs a voltage difference across the memory cell 201 generated according to a sensing current. The delay circuit 220 may delay a voltage of the sensing node and output the delayed voltage to a delay node. The delay circuit 220 may be implemented by an RC circuit, for example, which includes a resistor R and a capacitor C.

The sense amplifier 230 may be connected between the sensing node and the delay node. The sense amplifier 230 may output an output voltage Vout in response to a voltage difference between the sensing node and the delay node.

To detect whether a state of a memory cell is changed, the detector 200 may detect whether a peak is generated with respect to the output voltage Vout. The detector 200 may read data stored at the memory cell based on the detection result. The detector 200 may request a reprogramming operation on the memory cell 201 based on the detection result.

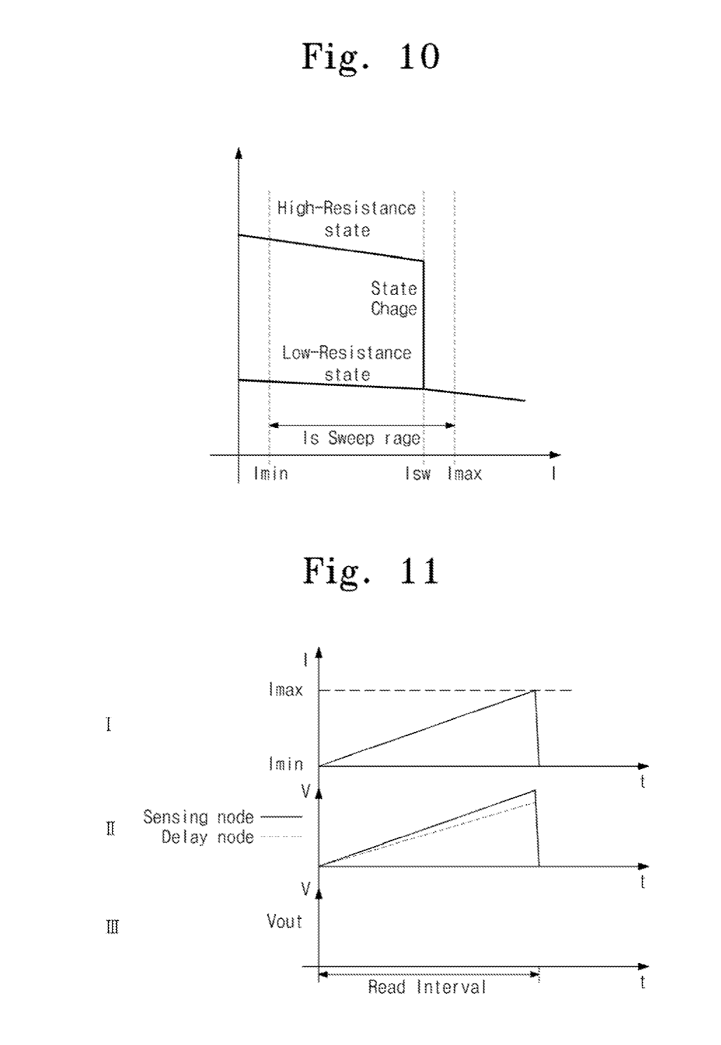

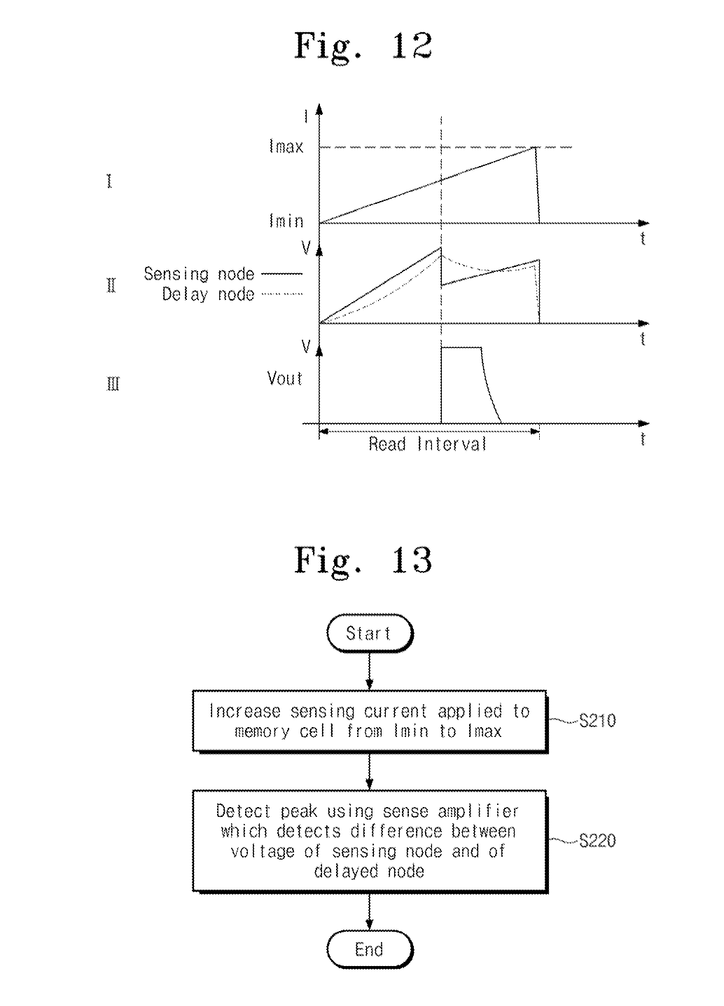

A relationship between a sensing current and an output voltage is more fully described herein with reference to FIGS. 11 and 12.

FIG. 11 are diagrams describing an output voltage when a memory cell is at a low resistance state before a read operation. In particular, FIG. 11 (I) is a graph illustrating a variation in a level of a sensing current by lapse of time, FIG. 11 (II) is a graph illustrating variations in voltage levels of sensing and delay nodes by lapse of time, and FIG. 11 (III) is a graph illustrating a variation in an output voltage by lapse of time.

Although a level of a sensing current can vary as described herein, in some embodiments, a state of a memory cell having a low resistance state does not change regardless of the varying level of the sensing current. In this case, voltages of the sensing and delay nodes may be stable. Thus, an output voltage may have a constant value, as shown in FIG. 11 (III).

FIG. 12 are diagrams describing an output voltage when a memory cell is at a high resistance state before a read operation. In particular, FIG. 12 (I) is a graph illustrating a variation in a level of a sensing current by lapse of time, FIG. 12 (II) is a graph illustrating variations in voltage levels of sensing and delay nodes by lapse of time, and FIG. 12 (III) is a graph illustrating a variation in an output voltage by lapse of time.

Referring to FIGS. 12 (I) and 12 (II), if a level of a sensing current is higher than that of a switching current, a state of a memory cell 201 (refer to FIG. 9) may be changed from a high resistance state to a low resistance state. In this case, a voltage of the sensing node (solid line) may sharply decrease. On the other hand, a voltage of the delay node (dotted line) may slowly decrease according to a time constant of a delay circuit 220 (refer to FIG. 9).

As illustrated in FIG. 12 III, when a state of a memory cell is changed, a voltage difference between the sensing node and the delay node may cause a peak of an output voltage. A detector 200 (refer to FIG. 9) may detect a variation in a state of a memory cell based on whether a peak of an output voltage is generated.

FIGS. 11 and 12 therefore illustrate an example where a sensing current linearly increases over time. However, the inventive concept is not limited thereto. For example, a sensing current may increase nonlinearly.

FIG. 13 is a flow diagram of an embodiment illustrating operations (S110 and S120) of reading data stored at a first memory cell and determining whether a state of the first memory cell is changed, for example, related to a read method of a nonvolatile memory device of FIG. 7.

A nonvolatile memory device according to a method of FIG. 13 may include a sensing current source, a sensing node, a delay node, and a sense amplifier. The sensing current source can be configured to supply a sensing current to a first memory cell. The sensing node can output a first output voltage in response to a voltage difference between both ends of the first memory cell. The delay node can delay a voltage of the sensing node and output a second output voltage in response to the delay voltage. The sense amplifier can be configured to sense a voltage difference between the sensing node and the delay node.

In operation S210, a sensing current may be applied to a memory cell, for example, memory cell 201 of FIG. 9. A level of the sensing current may be variable between a minimum current Imin and a maximum current Imax.

In operation S220, a detection result can be made with respect to whether a peak is generated at an output of the sense amplifier by a voltage difference between the sensing node and the delay node. Data stored at the first memory cell and reprogramming may be determined based on the detection result.

In the event that a peak is generated, data stored at the first memory cell may be processed, for example, determined as data corresponding to a high resistance state. Also, since a state of the first memory cell is changed during a read operation, a reprogramming step may be required. On the other hand, in the event that a peak is not generated, data stored at the first memory cell may be determined as being data corresponding to a low resistance state. Since a state of the first memory cell is maintained, reprogramming may not be required.

Accordingly, with the application of a read operation and the state variation detecting operation on the first memory cell according to the foregoing, a reference cell may not be required at a read operation, and compensation on a variation in a physical characteristic of the memory cell need not be required.

In FIGS. 9 to 13, an embodiment is described where switching from a high resistance state to a low resistance state is detected. However, the inventive concept is not limited thereto. For example, if an applying direction of a sensing current is opposite to that described above, then switching from a low resistance state to a high resistance state may be detected.

FIGS. 14 to 17 are diagrams describing an embodiment on an operation (S130) of performing a data processing operation on a second memory cell during execution of a reprogramming operation on a first memory cell, for example, in accordance with a read method of a nonvolatile memory device of FIG. 7.

Referring to a read method described with reference to FIGS. 14 to 17, a nonvolatile memory device may simultaneously perform data processing operations on a plurality of memory cells using a base voltage.

FIG. 14 is a diagram of a first memory cell MC1 and memory cells MCa, MCb, and MCc adjacent the first memory cell. Referring to FIG. 14, a first memory cell MC1 may be coupled between a word line WLn and a bit line BLm. A memory cell MCa may share the word line WLn together with the first memory cell MC1. A memory cell MCb may share the bit line BLm together with the first memory cell MC1. A memory cell MCc may be coupled between a different bit line and word line than those of which the first memory cell MC1 is coupled.

In operation S130 of FIG. 7, when a reprogramming operation on the first memory cell MC1 is performed, a data processing operation may be performed on a second memory cell selected following the first memory cell MC1.

In the event that the memory cell MCc is selected as the second memory cell, the first memory cell MC1 and the second memory cell may not share a bit line or a word line. A nonvolatile memory device may perform data processing operations on the first memory cell MC1 and the second memory cell in parallel.

In the event that the memory cell MCa is selected as the second memory cell, the first memory cell MC1 and the second memory cell may share the same word line WLn. The nonvolatile memory device may apply a base voltage to the word line WLn to perform a reprogramming operation on the first memory cell MC1 and a data processing operation on the second memory cell at the same time.

In the event that the memory cell MCb is selected as the second memory cell, the first memory cell MC1 and the second memory cell may share the same bit line BLm. The nonvolatile memory device may apply a base voltage to the bit line BLm to perform a reprogramming operation on the first memory cell MC1 and a data processing operation on the second memory cell at a same or similar time.

The base voltage Vb may be lower than a power supply voltage Vdd and higher than a source voltage Vss. The power supply voltage Vdd and the source voltage Vss may be a high voltage and a low voltage applied at a write or read operation.

For example, the base voltage Vb may be a voltage corresponding to an average of the power supply voltage Vdd and the source voltage Vss. In a case where the source voltage Vss is a ground voltage, the base voltage Vb may be Vdd/2. However, the inventive concept is not limited thereto.

FIG. 15 is a diagram describing a data processing operation in the event that a first memory cell MC1 and a second memory cell MC2 share a same source line. Referring to FIG. 15, a first memory cell MC1 and a second memory cell MC2 may share a common source line.

The first memory cell MC1 may be connected to the common source line and a bit line BLm. The second memory cell MC2 may be connected to the common source line and a bit line BLm+1.

A base voltage Vb may be applied to the common source line when a reprogramming operation on the first memory cell MC1 and a data processing operation on the second memory cell MC2 are performed.

A nonvolatile memory device may reprogram the first memory cell MC1 to have a desired state by adjusting a voltage or current applied to the bit line BLm. The nonvolatile memory device may perform a data processing operation on the second memory cell MC2 by adjusting a voltage or current applied to the bit line BLm+1, which can occur at or near the same time as the reprogramming operation. Since the base voltage Vb applied to the common source line is lower than a power supply voltage Vdd and higher than a source voltage Vss, levels and directions of currents flowing to the first and second memory cells MC1 and MC2 may be changed into required levels and directions, respectively, according to voltages and/or currents applied to the bit lines BLm and BLm+1.

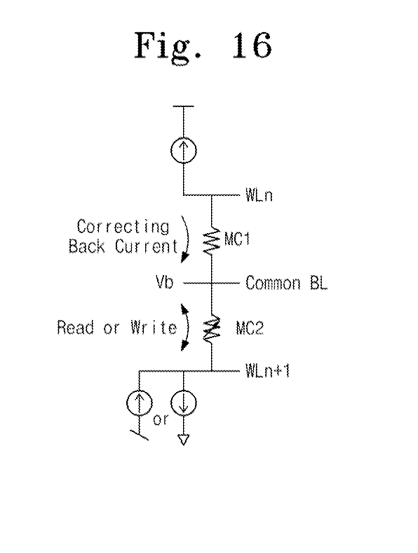

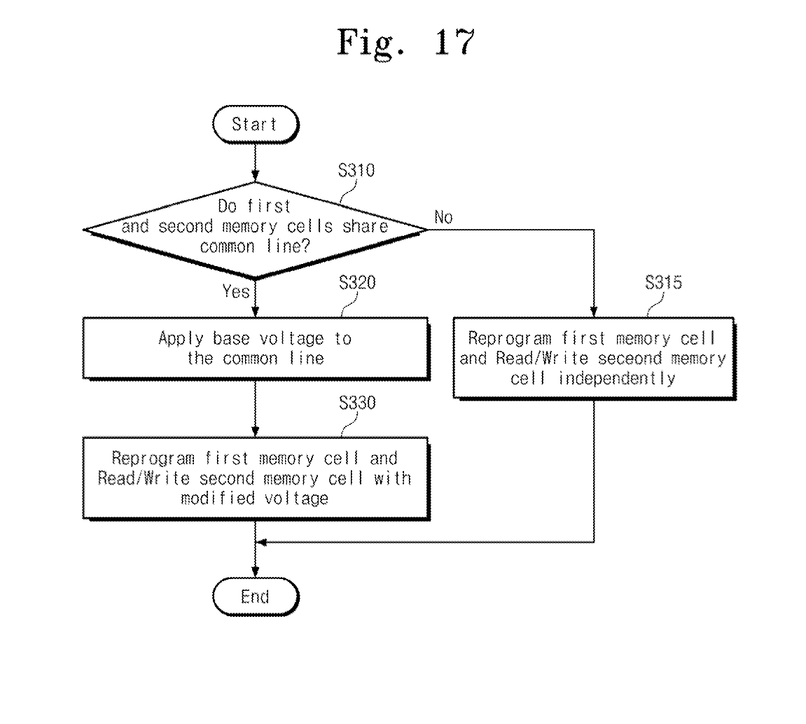

FIG. 16 is a diagram describing a data processing operation in the event that a first memory cell MC1 and a second memory cell MC2 share the same bit line. Referring to FIG. 16, a first memory cell MC1 and a second memory cell MC2 may share a common bit line.

The first memory cell MC1 may be connected to the common bit line and a source line SLn. The second memory cell MC2 may be connected to the common bit line and a source line SLn+1.

A base voltage Vb may be applied to the common bit line when a reprogramming operation on the first memory cell MC1 and a data processing operation on the second memory cell MC2 are performed.

A nonvolatile memory device may reprogram the first memory cell MC1 to have a desired state by adjusting a voltage or current applied to the source line SLn. The nonvolatile memory device may perform a data processing operation on the second memory cell MC2 by adjusting a voltage or current applied to the source line SLn+1, which can occur at or near the same time as the reprogramming operation. Since the base voltage Vb applied to the common bit line is lower than a power supply voltage Vdd and higher than a source voltage Vss, levels and directions of currents flowing to the first and second memory cells MC1 and MC2 may be changed into required levels and directions, respectively, according to voltages or currents applied to the source lines SLn and SLn+1.

As described with reference to FIGS. 15 and 16, the nonvolatile memory device may apply a base voltage to perform one or more data processing operations on a plurality of memory cells having different addresses at or near the same time. The base voltage may be applied to a common line, which is shared by those memory cells where data processing operations are executed at or near the same time. Accordingly, a data processing speed of the nonvolatile memory device by applying the base voltage in this manner may be improved.

FIG. 17 is a flow diagram describing an operation (S130) that includes performing a data processing operation on a second memory cell during execution of a reprogramming operation on a first memory cell, in accordance with an embodiment. The operation can be performed according to a read method related to a nonvolatile memory device, for example, described with respect to FIG. 7.

Referring to FIG. 17, a nonvolatile memory device may simultaneously perform data processing operations on a plurality of memory cells using a base voltage.

In operation S310, a determination may be made whether a first memory cell and a second memory cell share a common line. The common line may be a word line, a bit line or a source line shared by the first and second memory cells.

If the first and second memory cells don't share the common line, in operation S315, a reprogramming operation on the first memory cell and a data processing operation on the second memory cell may be performed in parallel.

If the first and second memory cells share the common line, in operation S320, a base voltage Vb may be applied to the common line. The base voltage Vb may be lower than a power supply voltage Vdd and higher than a source voltage Vss. The power supply voltage Vdd and the source voltage Vss may be a high voltage and a low voltage, respectively, applied at a write or read operation.

In operation S330, a reprogramming operation may be performed on the first memory cell and a data processing operation on the second memory cell. Since the base voltage applied to the common line exits between the power supply voltage Vdd and the source voltage Vss, both a read operation and a write operation on the second memory cell may be performed during the reprogramming operation of the first memory cell.

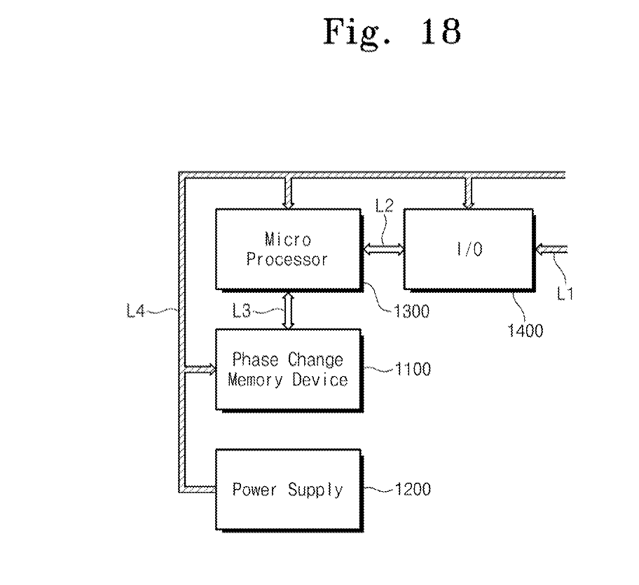

FIG. 18 is a block diagram schematically illustrating a portable electronic system including a phase change memory device 1100 constructed and arranged as a nonvolatile memory device according to an embodiment of the inventive concept. A phase change memory device 1100 may simultaneously perform a reprogramming operation and a data processing operation with respect to a plurality of memory cells having different addresses. Thus, the phase change memory device 1100 may perform a data processing operation having a fast operating speed and with high reliability.

The phase change memory device 1100 may be in communication with a microprocessor 1300 through a bus line L3 and used as a main memory of the portable electronic system. The system may include a power supply 1200 that supplies power through a power line L4 to the microprocessor 1300, an input/output device 1400, and the phase change memory device 1100. The microprocessor 1300 and the input/output device 1400 may constitute a memory controller controlling the phase change memory device 1100

In the event that input data is provided to the input/output device 1400 through a line L1, the microprocessor 1300 may process the input data provided through a line L2 to provide the input or processed data to the phase change memory device 1100. The phase change memory device 1100 may store data provided through the bus line L3 at one or more memory cells. Data stored at memory cells of the phase change memory device 1100 may be read by the microprocessor 1300 or output through the input/output device 1400 to an external device (not shown).

In the event that a power of the power supply 1200 is not supplied to the power line L4, data stored at one or more memory cells of the phase change memory device 1100 may be retained according to a characteristic of a phase change material, for example, due to the phase change memory device 1100 being nonvolatile unlike a conventional DRAM. In addition, the phase change memory device 1100 may have merits such as a fast operating speed and low power consumption.

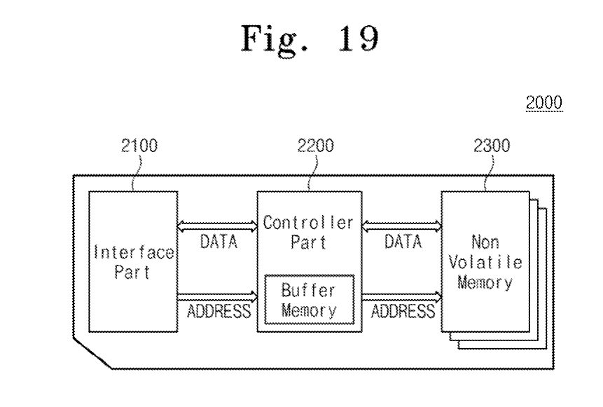

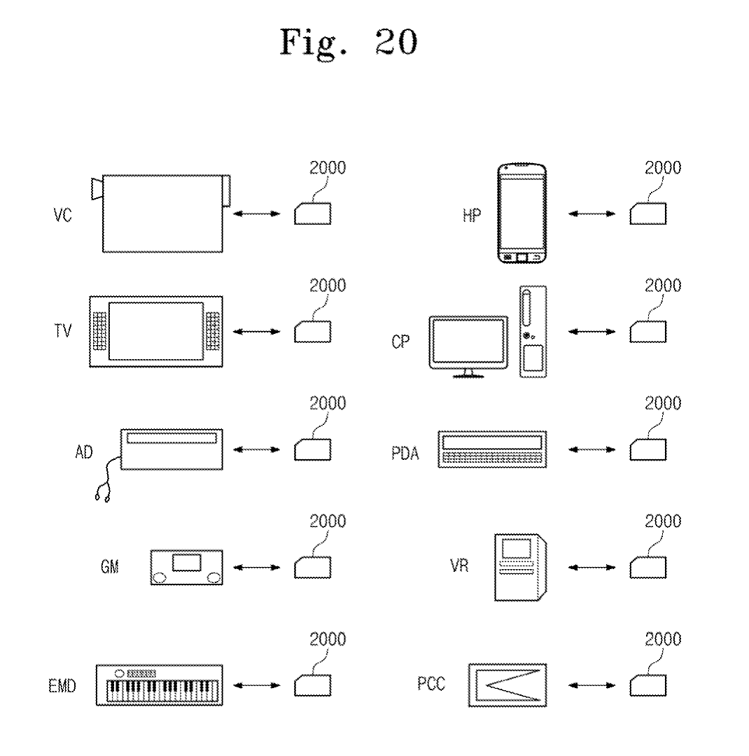

FIG. 19 is a block diagram schematically illustrating a memory card including a nonvolatile memory device according to an embodiment of the inventive concept. A memory card 2000, for example, may include but not limited to an MMC card, an SD card, a multiuse card, a micro-SD card, a memory stick, a compact SD card, an ID card, a PCMCIA card, an SSD card, a chip-card, a smartcard, an USB card, or the like.

Referring to FIG. 19, the memory card 2000 may include an interface circuit 2100 for interfacing with an external device, a controller 2200 including a buffer memory and controlling an operation of the memory card 2000, and at least one nonvolatile memory device 2300 according to an embodiment of the inventive concept. The controller 2200 may include a processor which is configured to control write and read operations related to the nonvolatile memory device 2300. The controller 2200 may communicate with the nonvolatile memory device 2300 and/or the interface circuit 2100 via a data bus and an address bus.

Since the nonvolatile memory device 2300 simultaneously performs a reprogramming operation and a data processing operation with respect to a plurality of memory cells having different addresses, it may perform a data processing operation in fast operating speed and with high reliability.

FIG. 20 is a diagram schematically illustrating various systems to which a memory card in FIG. 19 can be applied. Referring to FIG. 20, a memory card 2000 may be applied to but not limited to a video camera VC, a television TV, an audio device AD, a game machine GM, an electronic music device EMD, a cellular phone HP, a computer CP, a Personal Digital Assistant (PDA), a voice recorder VR, a PC card PCC, and the like.

A nonvolatile memory device according to the inventive concept may be packed using various types of packages. For example, a non-volatile memory device or a memory controller according to the inventive concept may be packed using packages such as PoP (Package on Package), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), and the like.

The inventive concept may be modified or changed variously. For example, a detailed structure of a voltage and current generator may be changed or modified variously according to environment and use. While the inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A nonvolatile memory device comprising:
a memory cell array including first and second memory cells, wherein data is stored at the first memory cell; and
an access control circuit configured to read the data stored at the first memory cell and to subsequently perform a data processing operation on the second memory cell contemporaneously with a reprogramming operation performed on the first memory cell,
wherein the reprogramming operation on the first memory cell is selectively performed based on a determination whether a state of the first memory cell is changed while the data stored at the first memory cell is read.

2. The nonvolatile memory device of claim 1, wherein the first and second memory cells share a common line, and wherein the access control circuit generates a base voltage that is output to the common line during the reprogramming operation performed on the first memory cell, the base voltage being higher than a ground voltage and lower than a power supply voltage.

3. The nonvolatile memory device of claim 2, wherein the common line includes a source line shared by the first and second memory cells.

4. The nonvolatile memory device of claim 2, wherein the common line includes a bit line shared by the first and second memory cells.

5. The nonvolatile memory device of claim 1, wherein the memory cell array includes one or more spin transfer torque magnetic random access memory (STT-MRAM) cells.

6. The nonvolatile memory device of claim 1, wherein the access control circuit comprises:
a sensing current source configured to provide the first memory cell with a sensing current variable between a first level and a second level, and wherein
the access control circuit reads data stored at the first memory cell in response to whether a state of the first memory cell is changed while the sensing current is provided.

7. The nonvolatile memory device of claim 6, wherein the reprogramming operation of the first memory cell is selectively performed in response to whether a state of the first memory cell is changed while the sensing current is provided.

8. The nonvolatile memory device of claim 6, wherein the first level is higher than a low switching current level and lower than a high switching current level, and wherein the low switching current level is a current level by which a state of the first memory cell is switched from a low resistance state to a high resistance state and the high switching current level is a current by which a state of the first memory cell is switched from the high resistance state from the low resistance state.

9. The nonvolatile memory device of claim 8, wherein the second level is higher than the high switching current level, and wherein in response to
a state of the first memory cell being changed while the sensing current is provided, data stored at the first memory cell is determined as data corresponding to a high resistance state.

10. The nonvolatile memory device of claim 8, wherein the second level is lower than the low switching current level, and wherein in response to a state of the first memory cell being changed while the sensing current is provided, data stored at the first memory cell is determined as data corresponding to a low resistance state.

11. The nonvolatile memory device of claim 6, wherein the access control circuit further comprises:
a sensing current source providing a sensing voltage output from the first memory cell in response to the sensing current;
a delay circuit configured to delay the sensing voltage to output the delayed sensing voltage to a delay node; and
a sense amplifier configured to provide an output voltage in response to a difference between the sensing voltage and the delayed sensing voltage, and wherein
whether a state of the first memory cell is changed while the sensing current is provided is determined based on the output voltage.

12. The nonvolatile memory device of claim 11, wherein the delay circuit comprises an element including a resistor and a capacitor.

13. A data processing method of a nonvolatile memory device, comprising:
determining whether a state of a first memory cell is changed while data stored at the first memory cell is read;
reprogramming the first memory cell when a state of the first memory cell is changed; and
performing a data processing operation on the second memory cell during a reprogramming operation performed on the first memory cell.

14. The data processing method of claim 13, wherein determining whether a state of the first memory cell is changed while data stored at the first memory cell is read comprises:
providing the first memory cell with a sensing current variable from a first level to a second level;
determining whether the state of the first memory cell is changed during an application of the sensing current; and
processing the data stored at the first memory cell in response to the determination whether a state of the first memory cell is changed.

15. The data processing method of claim 13, wherein performing the data processing operation on the second memory cell during reprogramming of the first memory cell comprises:
determining whether a common line shared by the first and second memory cells exists; and
in response to a determination that the common line exists, providing the common line with a base voltage higher than a ground voltage and lower than a power supply voltage.

16. A nonvolatile memory device comprising:
a plurality of memory cells, the memory cells comprising a first memory cell and a second memory cell, the first memory cell storing data; and
an access control circuit that reads the data stored at the first memory cell and determines whether a state of the first memory cell is changed while the data stored at the first memory cell is read, and that performs a data processing operation on the second memory cell during a reprogramming operation performed on the first memory cell.

17. The nonvolatile memory device of claim 16, further comprising a common line, wherein the common line comprises at least one of a bit line and a source line shared by the first and second memory cells.

18. The nonvolatile memory device of claim 16, wherein at least one of the first memory cell and the second memory cell includes one or more spin transfer torque magnetic random access memory (STT-MRAM) cells.

19. The nonvolatile memory device of claim 16, wherein the data processing operation performed on the second memory cell includes at least one of a read operation and a write operation.

20. The nonvolatile memory device of claim 16, wherein the access control unit provides the first memory cell with a sensing current variable from a first level to a second level, determines whether the state of the first memory cell is changed during an application of the sensing current, and processes the data stored at the first memory cell in response to the determination made by the access control unit whether the state of the first memory cell is changed.
